(19) United States
(12) Patent Application Publication
(10) Pub. No.: US 2019/0393434 A1
(43) Pub. Date: Dec. 26, 2019

(54) FLEXIBLE DISPLAY MOTHERBOARD AND FLEXIBLE DISPLAY PANEL

(71) Applicant: Kunshan Go-Visionox Opto-Electronics Co., Ltd., Kunshan (CN)

(72) Inventors: Mingxing LIU, Kunshan (CN); Xuliang WANG, Kunshan (CN); Feng GAO, Kunshan (CN); Shuaiyan GAN, Kunshan (CN); Xuan ZHANG, Kunshan (CN)

(21) Appl. No.: 16/562,447

(22) Filed: Sep. 6, 2019

Related U.S. Application Data
(63) Continuation of application No. PCT/CN2018/118988, filed on Dec. 3, 2018.

(30) Foreign Application Priority Data
Apr. 24, 2018 (CN) 201810373692.2

(51) Int. Cl. H01L 51/00; H01L 51/56; H01L 51/52; H01L 27/32

(52) U.S. Cl. CPC H01L 51/0097; H01L 51/56; H01L 51/529; H01L 27/3244; H01L 51/524; H01L 2251/5338; H01L 2251/566; H01L 27/323; H01L 51/5281; H01L 51/5253

(57) ABSTRACT

The present disclosure relates to a flexible display motherboard, including a plurality of display panel areas and a cuttable area surrounding the display panel areas. The flexible display motherboard includes a heat conductive pattern layer and a heat storage pattern layer both formed in the cuttable area. The heat conductive pattern layer is arranged along at least a portion of an edge of the display panel area to conduct cutting heat. The heat storage pattern layer surrounds the heat conductive pattern layer, and is connected to the heat conductive pattern layer, to store the cutting heat conducted by the heat conductive pattern layer.

### CROSS-REFERENCES TO RELATED APPLICATIONS

This application is a continuation application for International Application PCT/CN2018/118988, filed on Dec. 3, 2018, which claims the priority benefit of Chinese Patent Application No. 201810373692.2, titled “FLEXIBLE DISPLAY MOTHERBOARD AND FLEXIBLE DISPLAY PANEL” and filed on Apr. 24, 2018. The entireties of both applications are incorporated by reference herein for all purposes.

### TECHNICAL FIELD

The present disclosure relates to the field of display technologies.

### BACKGROUND

Currently, display technology has been widely used in all aspects of daily lives, and accordingly, more and more materials and technologies are used for display devices. In present, the popular display screens are mainly liquid crystal display screens and organic light emitting diode display screens. Among them, since the Organic Light-Emitting Diode (OLED) has self-luminous performance, compared with the liquid crystal display screen, a relatively large energy-consuming backlight module is omitted. The organic light-emitting diode display screen thus has an advantage of better energy saving. In addition, the organic light-emitting diode display screen is flexible and bendable, and thus is widely used.

### SUMMARY

In view of above, according to the present disclosure, provided are a flexible display motherboard and a flexible display panel, which can reduce the thermal expansion of the display panel film layer after heat absorption, thereby avoiding damage to the edge of the panel during the cutting process, to improve the production yield of display panels.

Provided is flexible display motherboard, including: a plurality of display panel areas; a cuttable area, surrounding the plurality of display panel areas; a heat conductive pattern layer being arranged along at least a portion of an edge of each of the display panel areas to conduct cutting heat and formed in the cuttable area; and a heat storage pattern layer being positioned surrounding the heat conductive pattern layer and formed in the cuttable area and connected to the heat conductive pattern layer to store the cutting heat conducted by the heat conductive pattern layer.

According to the above flexible display motherboard, during the process of cutting the flexible display motherboard, heat generated by the laser cutting is first dispersed by the heat conductive pattern layer, and then conducted to the heat storage pattern layer. The heat storage pattern layer stores the heat generated by the cutting, which reduces thermal expansion of the film layer of the flexible display panel caused by excessive absorption of heat, and avoids damage to the peripheral elements of the flexible display panel caused by the thermal expansion, to improve the production yield of flexible display panels.

In an embodiment, the cuttable area includes a first cuttable area extending lengthwise in a first direction, and a second cuttable area extending lengthwise in a second direction perpendicular to the first direction.

In an embodiment, the heat conductive pattern layer may include at least one of graphene, carbon nanotube paper, silver or copper.

In an embodiment, the heat storage pattern layer may include at least one of lithium, paraffin, polystyrene, aluminum or copper.

In an embodiment, a cutting line of the flexible display motherboard is positioned in an area of the heat conductive pattern layer.

In an embodiment, the heat conductive pattern layer includes a plurality of heat conductive portions spaced from each other along a lengthwise extending direction of the cuttable area.

In an embodiment, each heat conductive portion is characterized by an elongated shape.

In an embodiment, each heat conductive portion is lengthwise arranged in a width direction of the cuttable area.

In an embodiment, one end of each heat conductive portion in a lengthwise direction extends to the edge of the display panel area, and another end of the heat conductive portion in the lengthwise direction is connected to the heat storage pattern layer.

In an embodiment, the heat conductive pattern layer includes a plurality of hollowed patterns, and in a width direction of the cuttable area, two side boundaries of the hollowed pattern are located respectively on both sides of the cutting line of the flexible display motherboard.

In an embodiment, a cutting groove is formed on the heat conductive pattern layer along the cutting line of the flexible display motherboard.

Provided is a flexible display motherboard, including: a supporting substrate, comprising a plurality of display panel areas, and a cuttable area surrounding the display panel areas; a flexible substrate formed on the supporting substrate; a plurality of display elements formed on the flexible substrate, and corresponding to the display panel areas respectively; and a plurality of function film layer portions, each function film layer portion being formed on a corresponding one of the display elements, and corresponding to the display panel areas respectively.

The flexible display motherboard further includes a heat conductive pattern layer and a heat storage pattern layer both formed on the flexible substrate and located in the cuttable area; the heat conductive pattern layer is arranged along at least a portion of an edge of each of the display panel areas to conduct cutting heat; and the heat storage pattern layer surrounds the heat conductive pattern layer and is connected to the heat conductive pattern layer to store the cutting heat conducted by the heat conductive pattern layer.

In an embodiment, the flexible substrate is a bendable substrate, and the flexible substrate is at least one of a polyimide substrate, a polyamide substrate, a polycarbonate substrate or a polyphenylene ether sulfone substrate.

In an embodiment, the plurality of display elements include a thin-film transistor formed on the flexible substrate, an organic light-emitting element formed on the thin film transistor, and an encapsulation layer structure covering the organic light-emitting element, and the function film layer portion is located above the encapsulation layer structure.

In an embodiment, the function film layer portion includes a pressure sensitive adhesive layer and a polarizer, and the pressure sensitive adhesive layer covers the encapsulation layer structure.

Provided is a flexible display panel, obtained by cutting the flexible display motherboard described in the above embodiments along a side edge of the display panel area. The flexible display panel includes: a flexible substrate; a display element, formed on the flexible substrate, and corresponding to the display panel area; and a function film layer portion, formed on the display element, and corresponding to the display panel area.

In an embodiment, the flexible display panel further includes a touch control structure, a polarizer and a glass cover plate, the touch control structure is attached to the polarizer of the function film layer portion, and the touch control structure is covered by the glass cover plate.

During the process of cutting, heat generated by laser cutting is first dispersed by the heat conductive pattern layer, and then conducted to the heat storage pattern layer. The heat storage pattern layer stores the heat generated by the cutting, which reduces thermal expansion of the film layer of the flexible display panel caused by excessive absorption of heat, and avoids damage to the peripheral elements of the flexible display panel caused by the thermal expansion, to improve the production yield of flexible display panels. Further provided is a flexible display panel.

### BRIEF DESCRIPTION OF THE DRAWINGS

For the purpose of illustrating the technical solutions of the embodiments of the present disclosure more explicitly, the accompanying drawings to be used necessarily for the description of the embodiments will be briefly described below. Apparently, the accompanying drawings described below are part of the embodiments of the disclosure only, and accompanying drawings of the other embodiments may further be obtained based on these accompanying drawings herein without creative efforts to those of ordinary skill in the art.

FIG. 1 shows a structural diagram of a flexible display motherboard according to an embodiment of the present disclosure.

FIG. 2 shows a structural diagram of a heat conductive portion of the flexible display motherboard shown in FIG. 1.

### DETAILED DESCRIPTION OF THE INVENTION

The process for manufacturing the flexible display panel includes forming a plurality of flexible display panels on a large flexible display motherboard, and then cutting it to form separate flexible display panels. Generally, the cutting method for the flexible display panel is generally laser cutting. Due to the thermal influence between the laser and both the film material and the substrate, the edge of the display panel is easily destroyed, causing moisture to permeate from the side edge of the display panel, thereby damaging the OLED device, and causing abnormal display at the periphery of the flexible display panel.

To facilitate understanding the present disclosure, it will be described hereinafter more thoroughly in reference with the relative accompanying drawings. The preferred embodiments of the present disclosure are provided in the accompanying drawings. However, the present disclosure may be implemented in various forms, and not limited in the embodiments described herein. In contrast, the objective of providing these embodiments is to understand the disclosed description of the present disclosure more thoroughly.

For a better understanding of the technical solution of the present disclosure, the manufacturing of the flexible display panels will be described prior to the description of the flexible display motherboard of the present disclosure.

During the manufacturing of the flexible display panels, in order to reduce manufacturing costs and achieve large-scale mass production, it tends to manufacture a plurality of flexible display panels on a larger flexible display motherboard, and the flexible display motherboard is then cut into a plurality of separate flexible display panels by a cutting process. Therefore, the flexible display motherboard is an intermediate structure for manufacturing the flexible display panels. Generally, the flexible display motherboard includes a motherboard body and an encapsulation layer structure arranged on the motherboard body. The motherboard body has a plurality of display panel areas, and each display panel area is provided with an OLED device. The encapsulation layer structure includes a plurality of encapsulation structures corresponding to the plurality of display panel areas respectively. Each encapsulation structure is configured to encapsulate the OLED device in the corresponding display panel area.

Generally, the flexible display panel is obtained by laser cutting, which due to the thermal influence between the laser and both the film material and the substrate, damage (such as expansion or tear of the thin film encapsulation layer at the side edge) is easily resulted, so that moisture penetrates through the side edge of the flexible display panel, and further destroys the OLED device, making the display panel unable to achieve long-term excellent display performance.

Therefore, it is needed to provide a flexible display motherboard which can remove the cutting heat generated by the cutting, and reduce the thermal expansion of the display panel film layer after the heat absorption, to improve the production yield of the flexible display panels.

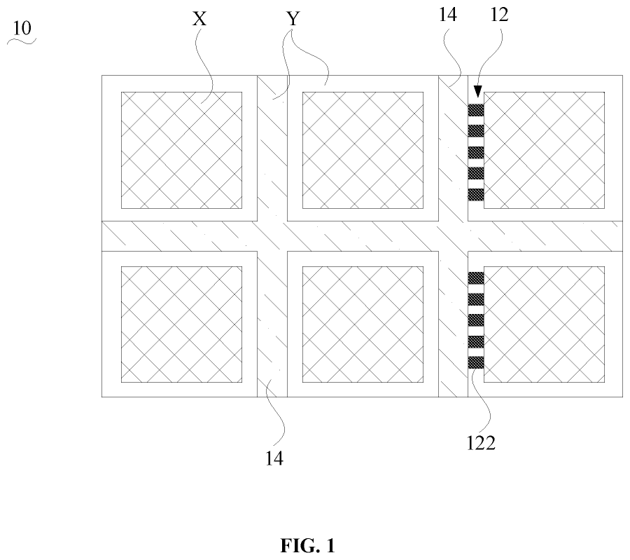

FIG. 1 shows a structural diagram of a flexible display motherboard 10 according to an embodiment of the present disclosure. For the convenience of description, only a portion of structures related to the embodiment of the present disclosure is shown. The flexible display motherboard 10 includes a plurality of display panel areas X, and a cuttable area Y surrounding the display panel areas X. The flexible display motherboard 10 further includes a heat conductive pattern layer 12 and a heat storage pattern layer 14 both formed in the cuttable area Y.

In an embodiment, one display panel area X refers to an area occupied by a portion essential for acquiring one flexible display panel from the flexible display motherboard 10 by cutting. The portion includes a display portion essential for realizing display, and another portion configured to provide wiring of a signal line for display or the like and not allowed to be cut off. For example, in some embodiments, one display panel area X of the flexible display motherboard 10 may include an active area (AA) configured to form the display screen subsequently, and may further include a non-active area (for example, including an area in which a driving circuit or a chip is arranged) for the display screen.

The cuttable area Y refers to an area adjacent to the display panel area X and occupied by a portion that is cuttable. For example, in some embodiments, the cuttable area Y includes a first cuttable area extending lengthwise in a first direction and a second cuttable area extending lengthwise in a second direction perpendicular to the first direction. Specifically, in the embodiment shown in FIG. 1, the first direction is a lateral direction as shown in FIG. 1, and the second direction is a longitudinal direction as shown in FIG. 1. The first cuttable area is an area extending in the lateral direction between any two adjacent display panel areas X, and the second cuttable area is an area extending in the longitudinal direction between any two adjacent display panel areas X.

In some embodiments, the cuttable area Y surrounds the display panel area X. In other embodiments, the cuttable area Y may form a closed area, or otherwise an unclosed area, which is not limited hereto.

In an embodiment of the present disclosure, the heat conductive pattern layer 12 and the heat storage pattern layer 14 are both formed in the cuttable area Y. The heat conductive pattern layer 12 is arranged along at least a portion of the edge of each display panel area X for conducting the cutting heat. The heat storage pattern layer 14 surrounds the heat conductive pattern layer 12, and is connected to the heat conductive pattern layer 12, and configured to store the cutting heat conducted by the heat conductive pattern layer 12. For example, in some embodiments, the heat conductive pattern layer 12 is formed in the first cuttable area in the first direction, and/or the heat conductive pattern layer 12 is formed in the second cuttable area in the second direction.

In such a way, during the process of cutting the flexible display motherboard 10, heat generated by laser cutting is first dispersed by the heat conductive pattern layer 12, and then conducted to the heat storage pattern layer 14. The heat storage pattern layer 14 stores the heat generated by the cutting, which reduces thermal expansion of the film layer of the flexible display panel caused by excessive absorption of heat, and avoids damage to the peripheral elements of the flexible display panel caused by the thermal expansion, to improve the production yield of flexible display panels.

For the flexible display motherboard 10, the display panel area includes a display area (such as active area) and a bezel area (such as non-active area) surrounding the display area. A boundary of the bezel area of the display panel area X may act as a boundary of the display panel area X. The heat storage pattern layer 14 surrounding the heat conductive pattern layer 12 means that the heat conductive pattern layer 12 is closer to the display panel area X than the heat storage pattern layer 14, that is, the heat storage pattern layer 14 surrounds the heat conductive pattern layer 12 from the outer side of the heat conductive pattern layer 12, thereby playing a role in rapid conduction of the cutting heat.

In an embodiment of the present disclosure, the heat conductive pattern layer 12 may be made of a unidirectional heat conductive material or a bidirectional heat conductive material, as long as the cutting heat is able to be conducted away from the display panel area X. In some embodiments, the heat conductive pattern layer 12 may be made of at least one of graphene, carbon nanotube paper, silver or copper. Of course, in other embodiments, the heat conductive pattern layer 12 may also be made of other heat conductive materials, which is not limited hereto.

In an embodiment of the present disclosure, the heat storage pattern layer 14 is made of a unidirectional heat conductive material, that is, after the cutting heat is conducted through the heat conductive pattern layer 12 to the unidirectional heat conductive material, the cutting heat can no longer be conducted back to the heat conductive pattern layer 12, thus avoiding the return of the cutting heat to the heat conductive pattern layer 12, thereby avoiding damage to the peripheral elements of the flexible display panels due to the thermal expansion, further improving the production yield of flexible display panels. In some embodiments, the heat storage pattern layer 14 may be made of at least one of lithium, paraffin, polystyrene, aluminum or copper. In other embodiments, the heat storage pattern layer 14 may also be made of other heat storage materials, which is not limited hereto.

In particular, the cuttable area Y and the heat conductive pattern layer 12 may be generally not completely removed due to the limitation of the precision of the cutting process. For example, in some embodiments, a cutting line of the flexible display motherboard 10 is located in the area of the heat conductive pattern layer 12, and the heat conductive pattern layer 12 partially extends into the display panel area X, and is partially embedded within the film layer of the display element. Specifically, during the cutting process, cutting may be performed along the cutting line in the cuttable area Y. In such a way, it is more advantageous for the heat conductive pattern layer 12 to conduct the cutting heat, which further reduces the thermal expansion of the film layer of the flexible display panel after heat absorption.

In some embodiments of the present disclosure, the heat conductive pattern layer 12 includes a plurality of heat conductive portions 122 spaced from each other along the lengthwise extending direction of the cuttable area Y. It should be understood that since the cutting line of the flexible display motherboard 10 is located in the area of the heat conductive pattern layer 12, and the heat conductive pattern layer 12 is made of some materials with better heat conductivity, such as graphene, silver or copper, or the like, if the heat conductive pattern layer 12 is a continuous pattern, the problem of affecting laser cutting exists. Therefore, the heat conductive pattern layer 12 is configured to include a plurality of heat conductive portions 122 spaced from each other, which reduces the area of the heat conductive pattern layer 12 affected by cutting along the cutting line, thereby reducing stress generated by the cutting force on the heat conductive pattern layer 12. In this way, the stress-transmitting carrier is reduced. Therefore, the influence of the heat conductive pattern layer 12 on the cutting and the breaking is avoided.

For example, in the embodiment shown in FIG. 1, the heat conductive portion 122 is in an elongated shape, and each heat conductive portion 122 is lengthwise arranged in a width direction of the cuttable area Y. Specifically, one end of each heat conductive portion 122 in a lengthwise direction extends to the edge of the display panel area X, and the other end is connected to the heat storage pattern layer 14, so as to conduct the cutting heat to the heat storage pattern layer 14.

In the above-mentioned implementation, in order to avoid the influence of the thermal conductive pattern layer 12 on the cutting and the breaking, the heat conductive pattern layer 12 includes a plurality of heat conductive portions 122 spaced from each other. In other embodiments, the heat conductive pattern layer 12 may also include a plurality of hollowed patterns, and in a width direction of the cuttable area Y, two side boundaries of the hollowed pattern are located respectively on both sides of the cutting line of the flexible display motherboard 10. During the process of cutting the flexible display motherboard 10, since the two side boundaries of the hollowed pattern are located respectively on the both sides of the cutting line, the cutting line passes through the hollowed pattern. Therefore, the cutting line acts only on a part of the heat conductive pattern layer 12 other than the hollowed pattern, which avoids the influence of the heat conductive pattern layer 12 on the cutting and the breaking, thereby improving the cutting quality and the production yield of flexible display panels.

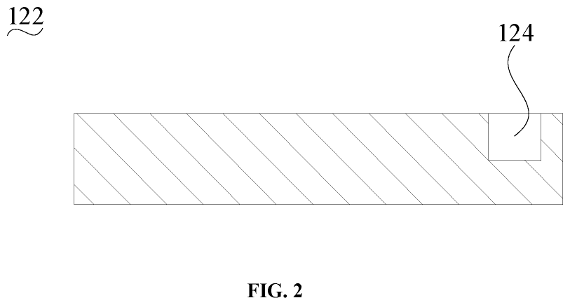

In some embodiments of the present disclosure, further referring to FIG. 2, a cutting groove 124 is formed on the heat conductive pattern layer 12 along the cutting line of the flexible display motherboard 10. In such a way, the magnitude of the stress generated by the cutting force on the heat conductive pattern layer 12 is further reduced, and the propagation carrier of the stress is also reduced, thereby avoiding the influence of the heat conductive pattern layer 12 on the cutting and the breaking.

Some embodiments of the present disclosure are further described in detail below.

As shown in the accompanying drawings, the flexible display motherboard 10 in some embodiments of the present disclosure includes a supporting substrate, a flexible substrate, a plurality of display elements, and a plurality of function film layer portions.

The supporting substrate includes a plurality of display panel areas X, and a cuttable area Y surrounding the display panel areas X. Specifically, in the embodiment shown in FIG. 1, the supporting substrate has six display panel areas X. The display panel area X defines the position of the flexible display panel. The display panel area X is in a shape of a rectangle, including four side edges.

The four side edges of each of the four display panel areas X in FIG. 1 may be lines that do not actually exist on the supporting substrate to mark the display panel area X. Alternatively, the four side edges may be marking lines existing on the supporting substrate. The four side edges may be used as cutting lines, along which the cutting is performed subsequently.

The flexible substrate is formed on the supporting substrate. The flexible substrate is a bendable substrate, optionally made of an organic polymer. For example, the flexible substrate may be at least one of a polyimide substrate, a polyamide substrate, a polycarbonate substrate, a polyphenylene ether sulfone substrate, or the like. In some embodiments, the flexible substrate may be obtained by coating polyimide glue liquid on the supporting substrate and curing the polyimide.

The plurality of display elements are formed on the flexible substrate, and correspond to the display panel areas X respectively. The plurality of function film layer portions are formed on the corresponding display elements, and correspond to the display panel areas X respectively. In some embodiments, the display element may include a thin film transistor formed on the flexible substrate, an organic light-emitting element formed on the thin film transistor, and an encapsulation layer structure covering the organic light-emitting element. The function film layer portion is located above the encapsulation layer structure.

In some specific embodiments, the encapsulation layer structure covers the organic light-emitting element to play a role in blocking moisture. When the organic light-emitting element is emitting light, electrons and holes are injected respectively between a transparent electrode layer acting as an anode and a metal electrode layer acting as a cathode, so that the electrons and holes are combined in the light-emitting layer, thereby causing the electrons to return from an excited state to a ground state. The excess energy is released in the form of light. The function film layer portion may include a pressure sensitive adhesive layer and a polarizer. The pressure sensitive adhesive layer covers the encapsulation layer structure. The polarizer is located on the pressure sensitive adhesive layer, and the glass cover plate is formed on the polarizer.

The heat conductive pattern layer 12 and the heat storage pattern layer 14 are formed on the flexible substrate, and located in the cuttable area Y. For example, in the embodiment shown in FIG. 1, the supporting substrate has six display panel areas X. Six display elements are formed on the flexible substrate, and six function film layer portions are formed on the corresponding display elements. An area of outer peripheries of the display panel areas X, and an area between any two adjacent display panel areas X forms the cuttable area Y as described above. The heat conductive pattern layer 12 and the heat storage pattern layer 14 are located in the cuttable area Y.

Based on the flexible display motherboard 10 described above, an embodiment of the present disclosure further provides a flexible display panel obtained by cutting along a side edge of the display panel area X of the flexible display motherboard 10 according to any one of the above embodiments.

The flexible display panel includes a flexible substrate, a display element, and a function film layer portion. The display element is formed on the flexible substrate, and corresponds to the display panel area X. Each function film layer portion is formed on the display element, and corresponds to the display panel area X.

In some embodiments, the flexible display panel further includes a touch control structure capable of detecting a touch on the outer side. The touch control structure includes a touch control electrode array and a plurality of touch control wirings. The touch control structure is attached to the polarizer of the function film layer portion, and a glass cover covers the touch control structure to protect the touch control structure. In some embodiments, the touch control structure may be bonded to the polarizer of the flexible display panel. In other embodiments, the touch control structure may be integrated into the package layer structure, which is not limited hereto.

In the above flexible display motherboard 10 and the flexible display panel, the heat conductive pattern layer 12 and the heat storage pattern layer 14 are arranged in the cuttable area Y. Accordingly, during the process of cutting the flexible display motherboard 10, heat generated by the laser cutting is first dispersed by the heat conductive pattern layer 12, and then conducted to the heat storage pattern layer 14. The heat storage pattern layer 14 stores the heat generated by the cutting, which reduces the thermal expansion caused by excessive absorption of heat by the film layer of the flexible display panel, and avoids damage to the peripheral elements of the flexible display panel caused by the thermal expansion, to improve the production yield of flexible display panels.

All of the technical features in the embodiments can be employed in arbitrary combinations. For purpose of simplifying the description, not all arbitrary combinations of the technical features in the embodiments illustrated above are described. However, as long as such combinations of the technical features are not contradictory, they should be considered as within the scope of the disclosure in the specification.

The above embodiments are merely illustrative of several implementations of the disclosure, and the description thereof is more specific and detailed, but should not be deemed as limitations to the scope of the present disclosure. It should be noted that variations and improvements will become apparent to those skilled in the art to which the present disclosure pertains without departing from its scope. Therefore, the scope of the present disclosure is defined by the appended claims.

1. A flexible display motherboard, comprising:
a plurality of display panel areas;
a cuttable area surrounding the plurality of display panel areas;
a heat conductive pattern layer being arranged along at least a portion of an edge of each of the display panel areas to conduct cutting heat and formed in the cuttable area; and
a heat storage pattern layer being positioned surrounding the heat conductive pattern layer and formed in the cuttable area and connected to the heat conductive pattern layer to store the cutting heat conducted by the heat conductive pattern layer.

2. The flexible display motherboard of claim 1, wherein the cuttable area comprises a first cuttable area extending lengthwise in a first direction, and a second cuttable area extending lengthwise in a second direction perpendicular to the first direction.

3. The flexible display motherboard of claim 1, wherein the heat conductive pattern layer comprises at least one of graphene, carbon nanotube paper, silver or copper, and the heat storage pattern layer comprises at least one of lithium, paraffin, polystyrene, aluminum or copper.

4. The flexible display motherboard of claim 1, wherein a cutting line of the flexible display motherboard is positioned in an area of the heat conductive pattern layer.

5. The flexible display motherboard of claim 4, wherein the heat conductive pattern layer comprises a plurality of heat conductive portions spaced from each other along a lengthwise extending direction of the cuttable area.

6. The flexible display motherboard of claim 5, wherein each heat conductive portion is characterized by an elongated shape.

7. The flexible display motherboard of claim 5, wherein each heat conductive portion is lengthwise arranged in a width direction of the cuttable area.

8. The flexible display motherboard of claim 6, wherein one end of each heat conductive portion in a lengthwise direction extends to the edge of the display panel area, and another end of the heat conductive portion in the lengthwise direction is connected to the heat storage pattern layer.

9. The flexible display motherboard of claim 4, wherein the heat conductive pattern layer comprises a plurality of hollowed patterns, and in a width direction of the cuttable area, two side boundaries of the hollowed pattern are located respectively on both sides of the cutting line of the flexible display motherboard.

10. The flexible display motherboard of claim 4, wherein a cutting groove is formed on the heat conductive pattern layer along the cutting line of the flexible display motherboard.

11. A flexible display motherboard, comprising:
a supporting substrate, comprising a plurality of display panel areas, and a cuttable area surrounding the display panel areas;
a flexible substrate, formed on the supporting substrate;
a plurality of display elements, formed on the flexible substrate, and corresponding to the display panel areas respectively; and
a plurality of function film layer portions, each function film layer portion being formed on a corresponding one of the display elements, and corresponding to the display panel areas respectively,
wherein the flexible display motherboard further comprises a heat conductive pattern layer and a heat storage pattern layer both formed on the flexible substrate and located in the cuttable area; the heat conductive pattern layer is arranged along at least a portion of an edge of each of the display panel areas to conduct cutting heat; and the heat storage pattern layer surrounds the heat conductive pattern layer and is connected to the heat conductive pattern layer to store the cutting heat conducted by the heat conductive pattern layer.

12. The flexible display motherboard of claim 11, wherein the flexible substrate is a bendable substrate, and the flexible substrate is at least one of a polyimide substrate, a polyamide substrate, a polycarbonate substrate or a polyphenylene ether sulfone substrate.

13. The flexible display motherboard of claim 11, wherein the plurality of display elements comprise a thin-film transistor formed on the flexible substrate, an organic light-emitting element formed on the thin film transistor, and an encapsulation layer structure covering the organic light-emitting element, and the function film layer portion is located above the encapsulation layer structure.

14. The flexible display motherboard of claim 13, wherein the function film layer portion comprises a pressure sensitive adhesive layer and a polarizer, and the pressure sensitive adhesive layer covers the encapsulation layer structure.

15. A flexible display panel, obtained by cutting the flexible display motherboard of claim 1 along a side edge of the display panel area, the flexible display panel comprising:
a flexible substrate;
a display element, formed on the flexible substrate, and corresponding to the display panel area; and
a function film layer portion, formed on the display element, and corresponding to the display panel area.

16. The flexible display panel of claim 15, wherein the flexible display panel further comprises a touch control structure, a polarizer and a glass cover plate, the touch control structure is attached to the polarizer of the function film layer portion, and the touch control structure is covered by the glass cover plate.
